(19) United States
(12) Patent Application Publication
(10) Pub. No.: US 2022/0293392 A1
(43) Pub. Date: Sep. 15, 2022

(54) COIL FOR IMPROVED PROCESS CHAMBER DEPOSITION AND ETCH UNIFORMITY

(71) Applicant: Applied Materials, Inc., Santa Clara, CA (US)

(72) Inventors: Rui Li, San Jose, CA (US); Andrew Tomko, Redwood City, CA (US); Xiangjin Xie, Fremont, CA (US); Goichi Yoshidome, Albany, CA (US)

(21) Appl. No.: 17/687,157

(22) Filed: Mar. 4, 2022

Related U.S. Application Data
(60) Provisional application No. 63/159,384, filed on Mar. 10, 2021.

(51) Int. Cl. H01J 37/32; H05H 1/46; H01J 37/34

(52) U.S. Cl. CPC H01J 37/3211; H05H 1/46; H01J 37/32174; H01J 37/34

(57) ABSTRACT

Embodiments of coils for use in process chambers are provided herein. In some embodiments, a coil for use in a process chamber includes: a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion; and a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

### CROSS-REFERENCE TO RELATED APPLICATIONS

This application claims benefit of U.S. provisional patent application Ser. No. 63/159,384, filed Mar. 10, 2021, which is herein incorporated by reference in its entirety.

### FIELD

Embodiments of the present disclosure generally relate to substrate processing equipment.

### BACKGROUND

The manufacture of the sub-half micron and smaller features in the semiconductor industry rely upon a variety of processing equipment, such as process chambers, for example, physical vapor deposition (PVD) chambers, chemical vapor deposition (CVD) chambers, atomic layer deposition (ALD) chambers, etch chambers, and the like. The process chambers may use coils disposed between a target and a substrate support of the process chamber to maintain a plasma in the process chamber. However, the inventors have observed that the geometry of the coil may lead to asymmetrical material deposition or material etch on a substrate being processed in the process chamber.

Therefore, the inventors have provided improved coils that help improve process uniformity in process chambers.

### SUMMARY

Embodiments of coils for use in process chambers are provided herein. In some embodiments, a coil for use in a process chamber includes: a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion; and a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

In some embodiments, a coil for use in a process chamber includes: a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion, and wherein the first end portion and the second end portion together span less than 180 degrees about a center of the coil body and the central portion spans greater than 180 degrees about the center of the coil body; and a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

In some embodiments, a process chamber, includes: a chamber body having an interior volume therein; a substrate support disposed in the interior volume; a target disposed in the interior volume opposite the substrate support; and a coil disposed in the interior volume between the target and the substrate support, wherein the coil comprises: a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion; and a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic cross-sectional view of a process chamber in accordance with at least some embodiments of the present disclosure.

FIG. 1B depicts a close-up cross-sectional view of an interface between a coil and an inner shield of a process chamber in accordance with at least some embodiments of the present disclosure.

FIG. 2A depicts an isometric view of a coil in accordance with at least some embodiments of the present disclosure.

FIG. 2B depicts a top view of a coil in accordance with at least some embodiments of the present disclosure.

FIG. 2C depicts a left side view of a coil in accordance with at least some embodiments of the present disclosure.

FIG. 2D depicts a front view of a coil in accordance with at least some embodiments of the present disclosure.

FIG. 2E depicts a cross-sectional view of a portion of a coil in accordance with at least some embodiments of the present disclosure.

FIG. 3A depicts an isometric view of a coil in accordance with at least some embodiments of the present disclosure.

FIG. 3B depicts a top view of a coil in accordance with at least some embodiments of the present disclosure.

FIG. 3C depicts a left side view of a coil in accordance with at least some embodiments of the present disclosure.

FIG. 3D depicts a front view of a coil in accordance with at least some embodiments of the present disclosure.

FIG. 3E depicts a cross-sectional view of a portion of a coil in accordance with at least some embodiments of the present disclosure.

FIG. 4 depicts an isometric view of a coil in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of coils for use in process chambers are provided herein. The embodiments of coils provided herein have geometries that advantageously promote uniform deposition or etching on a surface of a substrate being processed within the process chamber. For example, a height of the coil may be greater at locations that correspond with areas of less deposition or less etch rate on the substrate. The height of the coil may be greater with additional material below, above, or below and above, a central horizontal plane of the coil at the locations corresponding with areas of less deposition or less etch rate.

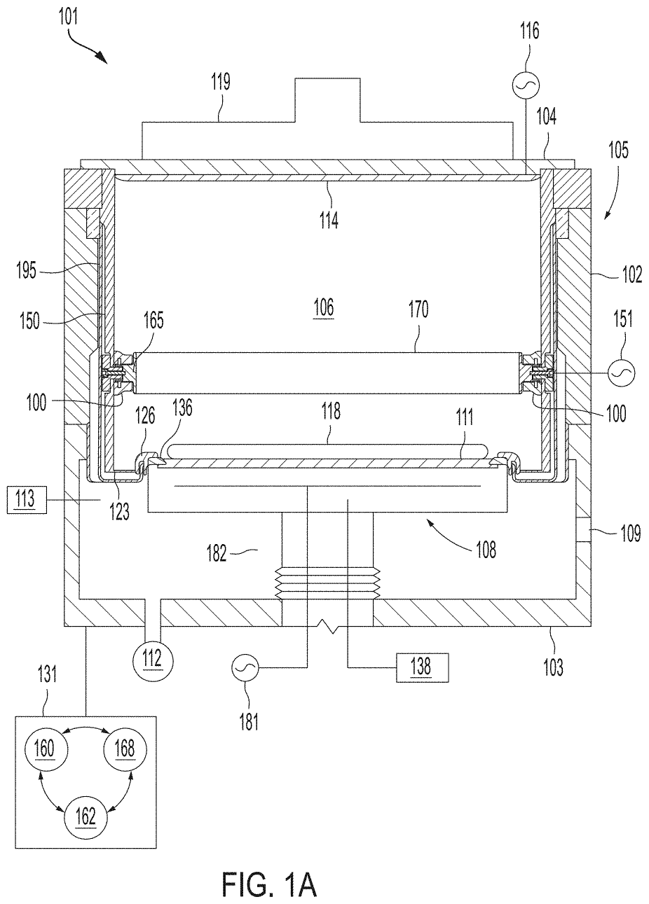

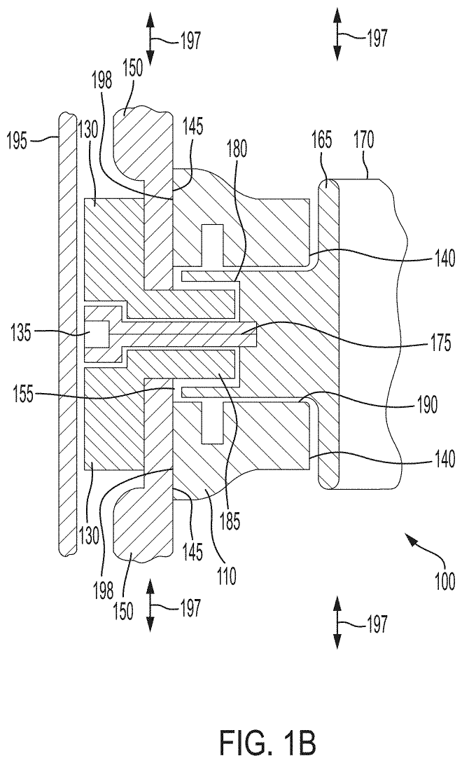

FIG. 1A depicts a schematic cross-sectional view of a process chamber 101 in accordance with at least some embodiments of the present disclosure. The process chamber 101 may be a PVD chamber or any other suitable deposition or etch chamber. The process chamber 101 has a body 105 that includes sidewalls 102, a bottom 103, and a lid 104 that encloses an interior volume 106. A substrate support, such as a pedestal 108, is disposed in the interior volume 106 of the process chamber 101. A substrate transfer port 109 is formed in the sidewalls 102 for transferring substrates into and out of the interior volume 106.

The lid 104 may support a sputtering source, such as a target 114. The target 114 generally provides a source of material which will be deposited in the substrate 118. The target 114 consists essentially of a metal, such as titanium (Ti), tantalum (Ta), tungsten (W), cobalt (Co), nickel (Ni), copper (Cu), aluminum (Al), ruthenium (Ru), niobium (Nb), alloys thereof, combinations thereof, or the like. In some embodiments, the target 114 is at least about 99.9% of a metal, such as titanium (Ti), tantalum (Ta), tungsten (W), cobalt (Co), nickel (Ni), copper (Cu), aluminum (Al), ruthenium (Ru), or niobium (Nb).

The target 114 may be coupled to a DC source power assembly 116. A magnetron 119 may be coupled adjacent to the target 114. Examples of the magnetron 119 assembly include an electromagnetic linear magnetron, a serpentine magnetron, a spiral magnetron, a double-digitated magnetron, a rectangularized spiral magnetron, among others. Alternately, powerful magnets may be placed adjacent to the target 114. The magnets may be rare earth magnets such as neodymium or other suitable materials for creating a strong magnetic field. The magnetron 119 may be configured to confine the plasma as well as distribute the concentration of plasma along the target 114.

A gas source 113 is coupled to the process chamber 101 to supply process gases into the interior volume 106. In some embodiments, process gases may include one or more inert gases or reactive gases. Examples of process gases that may be provided by the gas source 113 include, but not limited to, argon (Ar), helium (He), neon (Ne), nitrogen (N₂), oxygen (O₂), water vapor (H₂O), or the like.

A pumping device 112 is coupled to the process chamber 101 in communication with the interior volume 106 to control the pressure of the interior volume 106. In some embodiments, the pressure of the process chamber 101 may be maintained at about 1 Torr or less. In some embodiments, the pressure within the process chamber 101 may be maintained at about 500 millitorr or less. In other embodiments, the pressure within the process chamber 101 may be maintained between about 1 millitorr and about 300 millitorr.

In some embodiments, a controller 131 is coupled to the process chamber 101. The controller 131 includes a central processing unit (CPU) 160, a memory 168, and support circuits 162. The controller 131 is utilized to control the process sequence, regulating the gas flows from the gas source 113 into the process chamber 101 and controlling ion bombardment of the target 114. The CPU 160 may be of any form of a general-purpose computer processor that can be used in an industrial setting. The software routines can be stored in the memory 168, such as random-access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU 160 into a computer (controller 131) that controls the process chamber 101 such that the processes are performed in accordance with the present disclosure. The software routines may also be stored and/or executed by a second controller (not shown) that is located remotely from the process chamber 101.

An additional RF power source 181 may also be coupled to the process chamber 101 through the pedestal 108 to provide a bias power between the target 114 and the pedestal 108, as needed. In some embodiments, the RF power source 181 may provide power to the pedestal 108 to bias the substrate 118 at a frequency between about 1 MHz and about 100 MHz, such as about 13.56 MHz.

The pedestal 108 may be moveable between a raised position and a lowered position, as shown by arrow 182. In the lowered position, a top surface 111 of the pedestal 108 may be aligned with or just below the substrate transfer port 109 to facilitate entry and removal of the substrate 118 from the process chamber 101. The top surface 111 may have an edge deposition ring 136 sized to receive the substrate 118 thereon while protecting the pedestal 108 from plasma and deposited material. The pedestal 108 may be moved to the raised position closer to the target 114 for processing the substrate 118 in the process chamber 101. A cover ring 126 may engage the edge deposition ring 136 when the pedestal 108 is in the raised position. The cover ring 126 may prevent deposition material from bridging between the substrate 118 and the pedestal 108. When the pedestal 108 is in the lowered position, the cover ring 126 is suspended above the pedestal 108 and substrate 118 positioned thereon to allow for substrate transfer.

During substrate transfer, a robot blade (not shown) having the substrate 118 thereon is extended through the substrate transfer port 109. Lift pins (not shown) extend through the top surface 111 of the pedestal 108 to lift the substrate 118 from the top surface 111 of the pedestal 108, thus allowing space for the robot blade to pass between the substrate 118 and pedestal 108. The robot may then carry the substrate 118 out of the process chamber 101 through the substrate transfer port 109. Raising and lowering of the pedestal 108 and/or the lift pins may be controlled by the controller 131.

During sputter deposition, the temperature of the substrate 118 may be controlled by utilizing a thermal controller 138 disposed in the pedestal 108. The substrate 118 may be heated to a desired temperature for processing. After processing, the substrate 118 may be rapidly cooled utilizing the thermal controller 138 disposed in the pedestal 108. The thermal controller 138 controls the temperature of the substrate 118 and may be utilized to change the temperature of the substrate 118 from a first temperature to a second temperature in a matter of seconds to about a minute.

An inner shield 150 may be positioned in the interior volume 106 between the target 114 and the pedestal 108. The inner shield 150 may be formed of aluminum or stainless steel among other materials. In some embodiments, the inner shield 150 is formed from stainless steel. An outer shield 195 may be formed between the inner shield 150 and the sidewall 102. The outer shield 195 may be formed from aluminum or stainless steel among other materials. The outer shield 195 may extend past the inner shield 150 and is configured to support the cover ring 126 when the pedestal 108 is in the lowered position.

In some embodiments, the inner shield 150 includes a radial flange 123 that includes an inner diameter that is greater than an outer diameter of the inner shield 150. The radial flange 123 extends from the inner shield 150 at an angle of about ninety degrees or greater relative to the inside diameter surface of the inner shield 150. The radial flange 123 may be a circular ridge extending from the surface of the inner shield 150 and is generally adapted to mate with a recess formed in the cover ring 126 disposed on the pedestal 108. The recess may be a circular groove formed in the cover ring 126 which centers the cover ring 126 with respect to the longitudinal axis of the pedestal 108.

The process chamber 101 has a coil 170 disposed in the interior volume 106 between the target 114 and the pedestal 108. The coil 170 of the process chamber 101 may be just inside the inner shield 150 and positioned above the pedestal 108. In some embodiments, the coil 170 is positioned nearer to the pedestal 108 than the target 114. The coil 170 may be formed from a material similar in composition to the target 114, for example, any of the materials discussed above to act as a secondary sputtering target.

In some embodiments, the coil 170 is supported from the inner shield 150 by a plurality of chamber components, such as chamber component 100, which may comprise or consist of coil spacers 110 (see FIG. 1B). The coil spacers 110 may electrically isolate the coil 170 from the inner shield 150 and other chamber components. The coil 170 may be coupled to a power source 151. The power source 151 may be an RF power source, a DC power source, or both an RF power source and a DC power source. The power source 151 may have electrical leads which penetrate the sidewall 102 of the process chamber 101, the outer shield 195, the inner shield 150 and the coil spacers 110. The coil 170 includes a plurality of hubs 165 for providing power to the coil 170 and couple the coil 170 to the inner shield 150, or another chamber component. The electrical leads connect to one or more hubs of the plurality of hubs 165 on the coil 170 for providing power to the coil 170. One or more of the plurality of hubs 165 may have a plurality of insulated electrical connections for providing power to the coil 170. Additionally, the plurality of hubs 165 may be configured to interface with the coil spacers 110 and support the coil 170. In some embodiments, the power source 151 applies current to the coil 170 to induce an RF field within the process chamber 101 and couple power to the plasma for increasing the plasma density, i.e., concentration of reactive ions.

FIG. 1B depicts a close-up cross-sectional view of an interface between a coil 170 and the inner shield 150 in accordance with at least some embodiments of the present disclosure. The chamber component 100 may include a coil spacer 110. In some embodiments, the chamber component 100 includes only a coil spacer 110. The chamber component 100 may optionally include at least one hub receptor 130. A fastener 135 may be utilized to hold the hub receptor 130 and coil spacer 110 together to form the chamber component 100. For example, the fastener 135 may extend through the hub receptor 130 and into one of the plurality of hubs 165. In some embodiments, the fastener 135 may include a central channel 175 extending through the fastener 135 along an elongate axis of the fastener 135 to prevent air pockets between the fastener 135 and plurality of hubs 165.

The coil spacer 110 has a top portion 140 and a bottom portion 145. The bottom portion 145 may be disposed proximate the inner shield 150. The coil spacer 110, the hub receptor 130, and the fastener 135 may attach together to secure the coil spacer 110 to the inner shield 150. In some embodiments, the bottom portion 145 of the coil spacer 110 is disposed proximate an opening 155 between the coil 170 and the inner shield 150. The coil spacer 110 may facilitate maintaining the opening 155 between the coil 170 and the inner shield 150 to electrically isolate the coil 170 from the inner shield 150. In some embodiments, the inner shield 150 may have a feature (not shown) which inter-fits with a complimentary feature of the coil spacer 110 to locate and/or secure the coil spacer 110 to the inner shield 150. For example, the coil spacer 110 may have threads, ferrule, taper, or other structure suitable for attaching the coil spacer 110 to the inner shield 150.

The hub receptor 130 may serve as a backing or structural member for attaching the coil spacer 110 to the inner shield 150. Additionally, the hub receptor 130 or fastener 135 may interface with one of the plurality of hubs 165 of the coil 170. The hub receptor 130 may have receiving features 185 for forming a joint or connection with respective complimentary hub features 180 on the one of the plurality of hubs 165. In some embodiments, the hub features 180 and the receiving features 185 engage to form a structural connection between the one of the plurality of hubs 165 and the coil spacer 110 for supporting the coil 170. The receiving features 185 and the hub features 180 may be finger joints, tapered joint, or other suitable structure for forming a union between the plurality of hubs 165 and each of the coil spacers 110 suitable for supporting the coil 170. In some embodiments, the receiving features 185 may form part of an electrical connection.

One or more of the coil spacers 110 may have an electrical pathway (not shown in FIG. 1B) extending there through. The electrical pathway may be configured to provide an electrical connection between the plurality of hubs 165 on the coil 170 and the power source 151 for energizing the coil 170. Alternately, the coil spacers 110 may not provide an electrical pathway and the power for energizing the coil 170 is provided in another manner without passing through one of the coil spacers 110. The electrical pathway may be a conductive path for transmitting an electrical signal. Alternately, the electrical pathway may be a void or space which provides accessibility of electrical connections between the power source 151 and one or more of the plurality of hubs 165 of the coil 170.

The coil spacer 110 may be formed from a metal, such as stainless steel. In some embodiments, stainless steel powder having a size of 35-45 micrometers is a suitable precursor material as described further below. The coil spacer 110 may electrically isolate the coil 170 from the inner shield 150. The coil spacer 110 may have an opening 190. The opening 190 may be configured to accept one of the plurality of hubs 165. The opening 190 may be disposed in the top portion 140 and extend towards the bottom portion 145. In some embodiments, the opening 190 has a circular profile and is configured to accept one of the plurality of hubs 165 having a round shape. In another embodiment, the opening 190 is shaped to receive one of the plurality of hubs 165 having a complimentary inter-fitting shape.

In some embodiments, the coil spacer 110 includes a base plane 198 in alignment with an axis 197 and the bottom portion 145. The base plane 198 generally extends across bottom portion 145. FIG. 1B also shows the outer shield 195 adjacent the chamber component 100. While not connected with the chamber component 100, the outer shield 195 is shown aligned in parallel with the axis 197, the bottom portion 145, and the base plane 198.

In some embodiments, one or more of the coil spacer 110 or the coil 170 may have surfaces that are texturized to promote adhesion and minimize flaking of deposited material during operation of the process chamber 101. For example, although not visible in FIG. 1, the coil 170 may have an inner sidewall that is texturized.

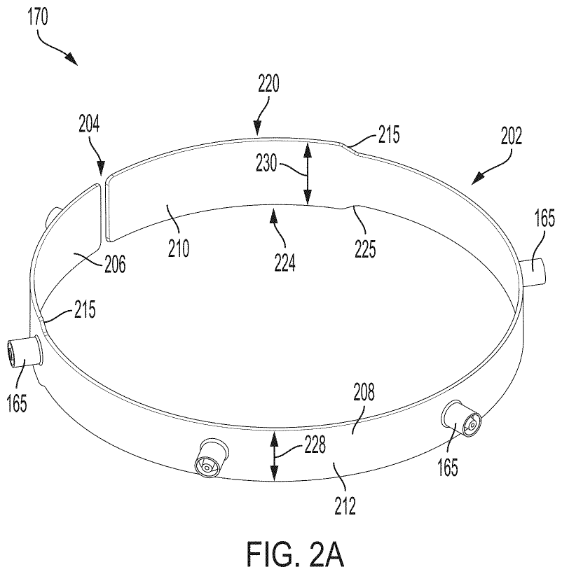

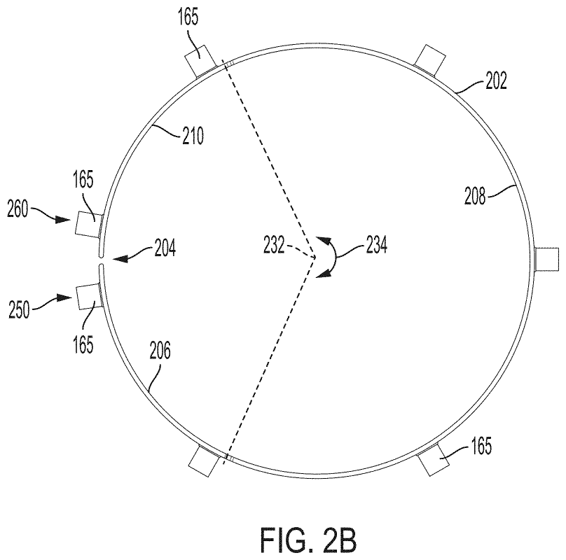

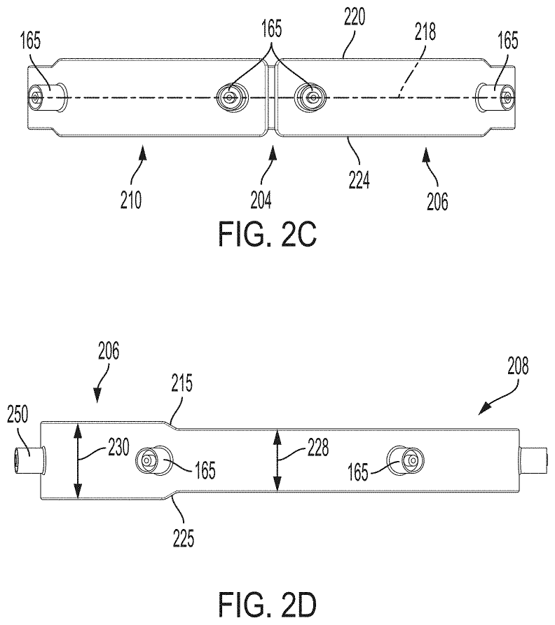

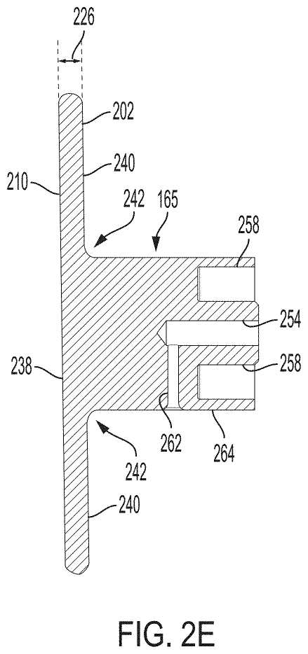

FIG. 2A through 2D depict an isometric view, a top view, a left side view, a front view, respectively, of a coil 170 in accordance with at least some embodiments of the present disclosure. The coil 170 generally includes a coil body 202 having a first end portion 206 and an opposing second end portion 210 coupled to the first end portion 206 via a central portion 208. The coil body 202 has an annular shape with the first end portion 206 and the second end portion 210 disposed adjacent to each other and spaced apart by a gap 204 forming a discontinuity in the annular shape. The gap 204 facilitates an electrical flow path from the first end portion 206 to the second end portion 210 via the central portion 208. In some embodiments, a width of the gap 204 is about 0.1 inches to about 0.5 inches. In some embodiments, the width of the gap 204 is substantially uniform. In some embodiments, the width of the gap 204 varies from an upper surface 220 of the coil body 202 to a lower surface 224 of the coil body 202. In some embodiments, the upper surface 220 and the lower surface 224 have rounded edges adjacent the gap 204. In some embodiments, the coil body 202 consists essentially of titanium (Ti), tantalum (Ta), tungsten (W), cobalt (Co), nickel (Ni), copper (Cu), aluminum (Al), ruthenium (Ru), niobium (Nb), alloys thereof, combinations thereof, or the like. In some embodiments, the coil body 202 consists essentially of the same material as the target 114.

In some embodiments, the first end portion 206 and the second end portion 210 together span less than 180 degrees about a center 232 of the coil body 202. In some embodiments, the central portion 208 has a central portion span 234 that spans greater than 180 degrees about the center 232 of the coil body 202. In some embodiments, the central portion span 234 is between about 180 to about 260 degrees. In some embodiments, a diameter of the coil body 202 is about 14 inches to about 16 inches. The central portion 208 may have a substantially uniform height. In some embodiments, the central portion 208 may have one or more taller portions having a height greater than a remainder of the central portion 208, where the one or more taller portions correspond with locations of the substrate 118 having areas of less deposition or less etch rate when the central portion 208 does not include the one or more taller portions.

In some embodiments, at least one of the first end portion 206 and the second end portion 210 have a height that is greater than a height of the central portion 208. In some embodiments, the height of the first end portion 206 and the second end portion 210 is about 2.0 inches to about 3.75 inches. In some embodiments, one of the first end portion 206 and the second end portion 210 have a height similar to the height of the central portion 208. In some embodiments, the height of the central portion is about 1.0 inches to about 2.5 inches. In some embodiments, as shown in FIGS. 2A to 2D, the height 230 of the first end portion 206 and the second end portion 210 is about 2.0 inches to about 3.0 inches. In some embodiments, as shown in FIGS. 2A to 2D, the height 228 of the central portion 208 is about 1.5 inches to about 2.5 inches. In some embodiments, the height 230 of the first end portion 206 and the second end portion 210 is substantially constant along the first end portion 206 and the second end portion 210.

The plurality of hubs 165 are coupled to an outer sidewall 212 of the coil body 202 and configured to facilitate coupling the coil 170 to the process chamber 101. Each of the first end portion 206 and the second end portion 210 are coupled to a hub of the plurality of hubs 165 configured to couple the coil 170 to the power source 151. For example, a first hub 250 of the plurality of hubs 165 may be coupled to the first end portion 206 proximate the gap 204 and a second hub 260 of the plurality of hubs 165 may be coupled to the second end portion 210 proximate the gap 204. In some embodiments, each of the first end portion 206 and the second end portion 210 include two hubs of the plurality hubs 165. In some embodiments, the plurality of hubs 165 are disposed at regular intervals about the center 232 of the coil body 202 from the first hub 250 to the second hub 260. In some embodiments, the regular intervals comprise about 50 to about 70 degrees about the center 232. In some embodiments, the plurality of hubs 165 comprise seven hubs.

In some embodiments, as shown in FIG. 2C, the plurality of hubs 165 are positioned along a central horizontal plate 218 of the coil body 202. In some embodiments, the plurality of hubs 165 are positioned along a horizontal plate of the coil body 202 between the central horizontal plate 218 and the lower surface 224. In some embodiments, the plurality of hubs 165 are positioned along a horizontal plate of the coil body 202 between the central horizontal plate 218 and the upper surface 220.

In some embodiments, the upper surface 220 of the coil body 202 includes first sloped portions 215 that extend upward from the central portion 208 to each of the first end portion 206 and the second end portion 210. In some embodiments, the lower surface 224 of the coil body 202 includes second sloped portions 225 that extend downward from the central portion 208 to each of the first end portion 206 and the second end portion 210. In some embodiments, a height of the coil body 202 tapers from each of the first end portion 206 and the second end portion 210 to the central portion 208 along the first sloped portions 215 and the second sloped portions 225, respectively. In some embodiments, the first sloped portions 215 extend at an angle similar to the second sloped portions 225 in an opposite direction to corresponding ones of the first sloped portions 225.

FIG. 2E depicts a cross-sectional view of a portion of the coil 170 of FIG. 2A in accordance with at least some embodiments of the present disclosure. In some embodiments, the hub features 180 of the plurality of hubs 165 include a central opening 254 for receiving a fastener (e.g., fastener 135). In some embodiments, an air channel 262 may extend from the central opening 254 to an outer surface 264 of the plurality of hubs 165 configured to advantageously prevent trapped air to be disposed in the central opening 254 when the fastener 135 is placed in the central opening 254. In some embodiments, the hub features 180 of the plurality of hubs 165 include an annular channel 258 disposed about the central opening 254. In some embodiments, the coil body 202 has a thickness 226 of about 0.75 inches to about 2.0 inches.

The coil body 202 or portions of the coil body 202 may be texturized to advantageously promote adhesion of deposited materials and mitigate flaking of deposited materials. In some embodiments, an inner sidewall 238 of the coil body 202 is texturized. In some embodiments, at least a portion of the outer sidewall 240 of the coil body 202 is texturized. In some embodiments, an interface 242 between the coil body 202 and the plurality of hubs 165 is texturized. The coil body 202 may be texturized via any suitable method, for example, via bead blasting, arc spraying, additive manufacturing such as 3-D printing, or the like. In some embodiments, different portions of the coil body 202 may be texturized via different methods. The texturized surfaces of the coil 170 may form any suitable design such as dimples, knurled pattern, honeycomb, or the like.

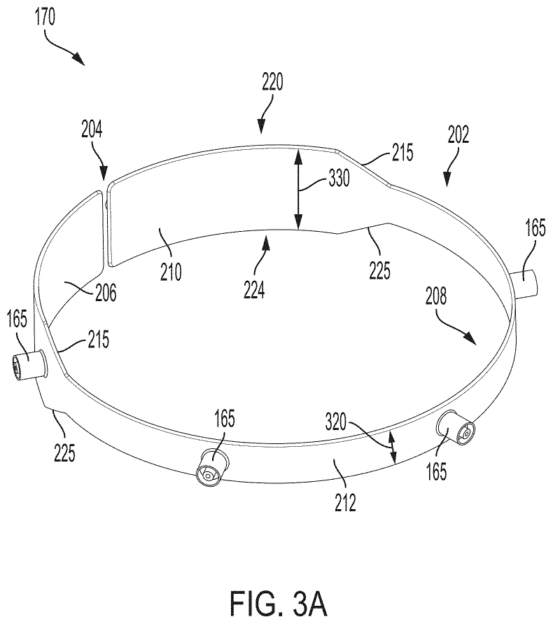

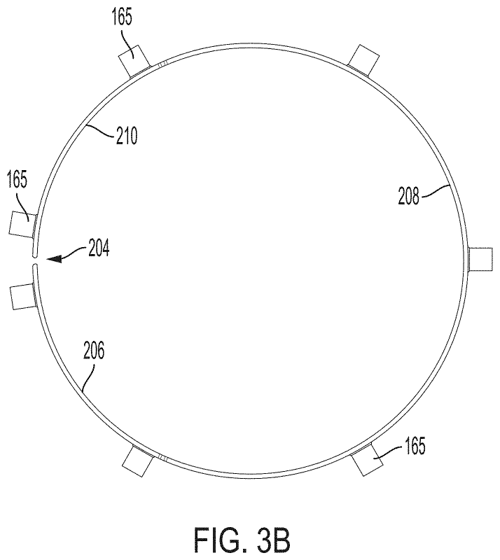

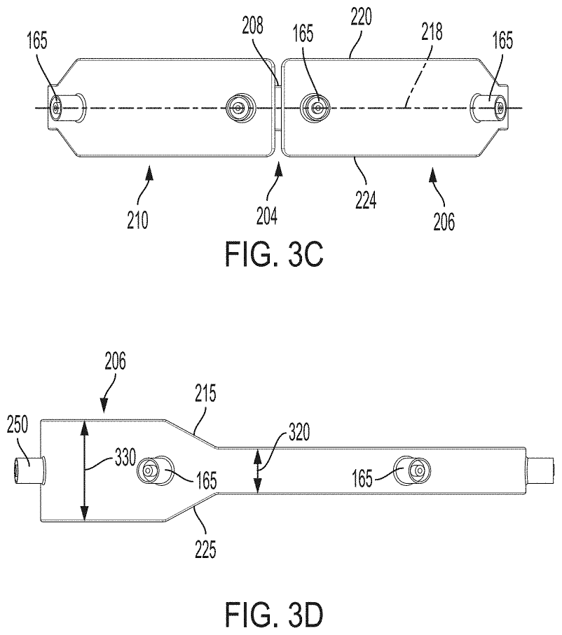

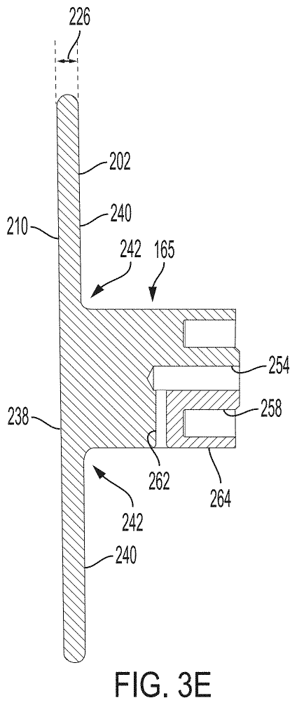

FIG. 3A through 3D depict an isometric view, a top view, a left side view, a front view, respectively, of a coil 170 in accordance with at least some embodiments of the present disclosure. FIG. 3E depicts a cross-sectional view of a portion of the coil 170 of FIG. 3A in accordance with at least some embodiments of the present disclosure. The coil 170 of FIGS. 3A through 3E is similar to the coil 170 of FIGS. 2A through 2E except for certain dimensions of the coil body 202. For example, a height 330 of the first end portion 206 and the second end portion 210 may be greater than the height 230. In some embodiments, a height 320 of the central portion 308 may be less than the height 228. In some embodiments, as shown in FIGS. 3A to 3E, the height 330 of the first end portion 206 and the second end portion 210 is about 2.5 inches to about 3.75 inches. In some embodiments, as shown in FIGS. 3A to 3E, the height 320 of the central portion 208 is about 1.0 inches to about 2.0 inches.

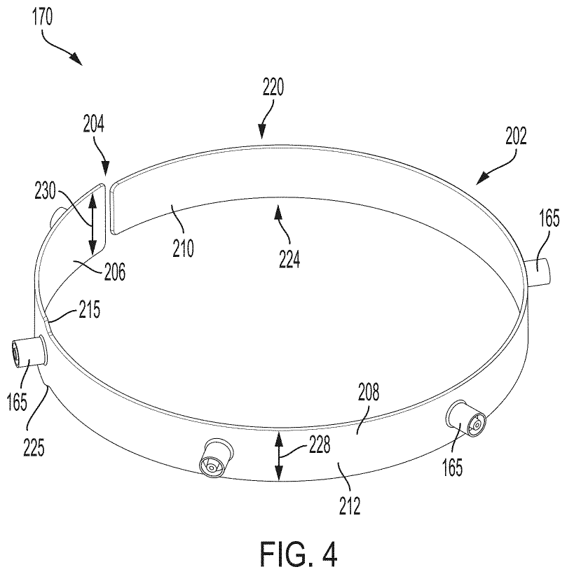

FIG. 4 depicts an isometric view of a coil 170 in accordance with at least some embodiments of the present disclosure. In some embodiments, as shown in FIG. 4, the coil 170 has an asymmetric geometry. In some embodiments, one of the first end portion 206 and the second end portion 210 have a height greater than a height 228 of the central portion 208. For example, as shown in FIG. 4, the coil 170 is similar to the coil 170 of FIG. 2A, except the second end portion 210 has a height similar to the height 228 of the central portion 208. In some embodiments, the coil body 202 includes the first sloped portions 215 on the upper surface 220 and does not include the second sloped portions 225 on the lower surface 224 (lower surface is substantially flat). In some embodiments, the coil body 202 does not include the first sloped portions 215 on the upper surface 220 (upper surface is substantially flat) and includes the second sloped portions 225 on the lower surface 224. The coil 170 as depicted in FIG. 4 may be otherwise similar to any of the other embodiments disclosed above.

While the foregoing is directed to embodiments of the present disclosure, other and further embodiments of the disclosure may be devised without departing from the basic scope thereof.

1. A coil for use in a process chamber, comprising:
a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion; and
a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

2. The coil of claim 1, wherein at least one of:
the height of the first end portion and the second end portion is about 2.0 inches to about 3.75 inches, or
the height of the central portion is about 1.0 inches to about 2.5 inches.

3. The coil of claim 1, wherein an inner sidewall of the coil body is texturized to promote adhesion of deposited materials.

4. The coil of claim 1, wherein the plurality of hubs comprises seven hubs.

5. The coil of claim 1, wherein each of the plurality of hubs are positioned along a central horizontal plate of the coil body.

6. The coil of claim 1, wherein the coil body has a thickness of about 0.75 inches to about 2.0 inches.

7. The coil of claim 1, wherein an upper surface of the coil body includes first sloped portions that extend upward from the central portion to each of the first end portion and the second end portion.

8. The coil of claim 1, wherein the plurality of hubs include a central opening for receiving a fastener.

9. The coil of claim 1, wherein the coil body consists essentially of titanium (Ti), tantalum (Ta), tungsten (W), cobalt (Co), nickel (Ni), copper (Cu), aluminum (Al), ruthenium (Ru), niobium (Nb), alloys thereof, or combinations thereof.

10. A coil for use in a process chamber, comprising:
a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein at least one of the first end portion and the second end portion have a height that is greater than a height of the central portion, and wherein the first end portion and the second end portion together span less than 180 degrees about a center of the coil body and the central portion spans greater than 180 degrees about the center of the coil body; and
a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

11. The coil of claim 10, wherein a width of the gap is about 0.1 inches to about 0.5 inches.

12. The coil of claim 10, wherein an inner sidewall of the coil body is texturized and at least a portion of the outer sidewall of the coil body is texturized.

13. The coil of claim 10, wherein the height of the first end portion and the second end portion is about 2.0 inches to about 3.5 inches and the height of the central portion is about 1.0 inches to about 2.5 inches.

14. The coil of claim 10, wherein a diameter of the coil body is about 14 inches to about 16 inches.

15. The coil of claim 10, wherein the height of the first end portion and the second end portion is substantially constant.

16. A process chamber, comprising:
a chamber body having an interior volume therein;
a pedestal disposed in the interior volume configured to support a substrate;
a target disposed in the interior volume opposite the pedestal; and
a coil disposed in the interior volume between the target and the pedestal, wherein the coil comprises:
a coil body having a first end portion and an opposing second end portion coupled to the first end portion via a central portion, the coil body having an annular shape with the first end portion and the second end portion disposed adjacent to each other and spaced apart by a gap forming a discontinuity in the annular shape, wherein one or more of the first end portion and the second end portion have a height that is greater than a height of the central portion; and
a plurality of hubs coupled to an outer sidewall of the coil body and configured to facilitate coupling the coil to the process chamber, wherein a hub of the plurality of hubs is coupled to each of the first end portion and the second end portion and configured to couple the coil to a power source.

17. The process chamber of claim 16, further comprising a power source coupled to the coil via the plurality of hubs.

18. The process chamber of claim 16, further comprising an inner shield positioned in the interior volume between the target and the pedestal, wherein the coil is coupled to the inner shield via the plurality of hubs.

19. The process chamber of claim 18, further comprising coil spacers disposed between the plurality of hubs and the inner shield to electrically isolate the coil from the inner shield.

20. The process chamber of claim 16, wherein the coil body is made of the same material as the target.
